(19) United States
(12) Patent Application Publication
(10) Pub. No.: US 2025/0201282 A1
(43) Pub. Date: Jun. 19, 2025

(54) AUTOMATIC SINGLE-USE-DEVICE VOLTAGE COMPATIBILITY

(71) Applicant: Boston Scientific Scimed, Inc., Maple Grove, MN (US)

(72) Inventors: Steven Kinio, Pickering (CA); Laurentiu Murtescu, Maple (CA); Cynthia Leung, Toronto (CA)

(21) Appl. No.: 18/972,688

(22) Filed: Dec. 6, 2024

Related U.S. Application Data
(60) Provisional application No. 63/610,801, filed on Dec. 15, 2023.

(51) Int. Cl. G11C 5/14

(52) U.S. Cl. CPC G11C 5/147; G11C 5/143

(57) ABSTRACT

A system for adapting long-lived capital equipment to changing single-use-device data storage technology includes one or more memory devices storing instructions and one or more processors configured to execute the instructions to perform operations. The system includes a power supply configured to convert AC power into a plurality of DC voltages. A selector is configured to select one of the plurality of DC voltages. A level shifter is configured to receive the selected one of the plurality of DC voltages and to translate a single-use-device data storage voltage to the selected one of the plurality of DC voltages.

### CROSS REFERENCE TO RELATED APPLICATIONS

This application claims priority to U.S. Provisional Patent Application No. 63/610,801 entitled “AUTOMATIC SINGLE-USE-DEVICE VOLTAGE COMPATIBILITY,” filed Dec. 15, 2023, which is incorporated herein by reference in its entirety.

### TECHNICAL FIELD

The present disclosure relates to adapting long-lived capital equipment systems to changing single-use-device data storage technology.

### BACKGROUND

Capital equipment is not consumed in the normal course of business and often times has long service lives. Capital equipment systems in the medical field can include control systems, RF generators, imaging systems, diagnostic equipment, monitors, and other systems. Over the lifetime of capital equipment systems, single-use-device (SUD) data storage technology can undergo changes. Single-use-device (SUD) data storage includes EEPROM as well as other data storage devices.

One factor that has changed multiple times in recent years for EEPROM is voltage logic levels. The standard voltage level used for EEPROM communication has changed over time from 5V to 3.3V, with some devices dropping their voltage to 2.5V or even 1.8V. As older systems designed for 5V logic fail or require upgrade, it can be difficult to find viable substitute SUD data storage. At some point, 5V logic will become obsolete, requiring potential hardware changes to capital systems in order to allow them to communicate with more contemporary SUD data storage. A need exists to enable long lived capital equipment systems to be easily adapted to changing SUD data storage technology.

### SUMMARY

Example 1 is a system for adapting long-lived capital equipment to changing single-use-device data storage technology. The system includes a power supply configured to convert AC power into a plurality of DC voltages. A selector is configured to select one of the plurality of DC voltages. The system includes a level shifter configured to receive the selected one of the plurality of DC voltages and to translate a single-use-device data storage voltage to the selected one of the plurality of DC voltages.

Example 2 is the system of Example 1, wherein the selector is a manual voltage rail selector.

Example 3 is the system of Example 1, wherein the selector is a digital switch voltage rail selector or a digitally controlled voltage rail that is controlled by a configuration file.

Example 4 is the system of Example 3, further comprising a binary presence feature configured to identity that a single-use-device data storage is connected to the system.

Example 5 is the system of Example 4, wherein the configuration file controls the digital switch voltage rail selector based on information from the binary presence feature.

Example 6 is the system of Example 1, the system including one or more memory devices storing instructions; and one or more processors configured to execute the instructions to perform operations.

Example 7 is the system of Example 6, wherein the operations include detecting the presence of a single-use-device data storage, selecting a first voltage of the plurality of DC voltages, the first voltage being a lowest of the plurality of DC voltages, and translating a single-use-device data storage voltage to the first voltage of the plurality of DC voltages.

Example 8 is the system of Example 7, wherein the operations include performing a first test message exchange with the detected single use storage device.

Example 9 is the system of Example 8, wherein the operations include locking in the first voltage of the plurality of DC voltages at the selector if the first test message exchange is successful.

Example 10 is the system of claim 8, wherein the operations include selecting a second voltage of the plurality of DC voltages, the second voltage being a higher voltage than the first voltage of the plurality of DC voltages, if the first test message exchange is unsuccessful, and translating the single-use-device data storage voltage to the second voltage of the plurality of DC voltages.

Example 11 is the system of Example 10, wherein the operations include performing a second test message exchange with the detected single use storage device.

Example 12 is the system of Example 11, wherein the operations include locking in the second voltage of the plurality of DC voltages at the selector if the second test message exchange is successful.

Example 13 is the system of claim 11, wherein the operations include selecting a third voltage of the plurality of DC voltages, the third voltage being a higher voltage than the second voltage of the plurality of DC voltages, if the second test message exchange is unsuccessful, and translating the single-use-device data storage voltage to the third voltage of the plurality of DC voltages.

Example 14 is the system of Example 13, wherein the operations include performing a third test message exchange with the detected single use storage device.

Example 15 is the system of Example 14, wherein the operations include locking in the third voltage of the plurality of DC voltages at the selector if the third test message exchange is successful.

Example 16 is a system for adapting long-lived capital equipment to changing single-use-device data storage technology. The system includes one or more memory devices storing instructions and one or more processors configured to execute the instructions to perform operations. The system includes a power supply configured to convert AC power into a plurality of DC voltages. A selector is configured to select one of the plurality of DC voltages. A level shifter is configured to receive the selected one of the plurality of DC voltages and to translate a single-use-device data storage voltage to the selected one of the plurality of DC voltages.

Example 17 is the system of Example 16, wherein the selector is a manual voltage rail selector.

Example 18 is the system of Example 16, wherein the selector is a digital switch voltage rail selector or a digitally controlled voltage rail that is controlled by a configuration file.

Example 19 is the system of Example 18, further comprising a binary presence feature configured to identity that a single-use-device data storage is connected to the system.

Example 20 is the system of Example 19, wherein the configuration file controls the digital switch voltage rail selector based on information from the binary presence feature.

Example 21 is the system of Example 16, wherein the operations include detecting the presence of a single-use-device data storage, selecting a first voltage of the plurality of DC voltages, the first voltage being a lowest of the plurality of DC voltages, and translating a single-use-device data storage voltage to the first voltage of the plurality of DC voltages.

Example 22 is the system of Example 21, wherein the operations include performing a first test message exchange with the detected single use storage device.

Example 23 is the system of Example 22, wherein the operations include locking in the first voltage of the plurality of DC voltages at the selector if the first test message exchange is successful.

Example 24 is the system of Example 22, wherein the operations include selecting a second voltage of the plurality of DC voltages, the second voltage being a higher voltage than the first voltage of the plurality of DC voltages, if the first test message exchange is unsuccessful, and translating the single-use-device data storage voltage to the second voltage of the plurality of DC voltages.

Example 25 is the system of Example 24, wherein the operations include performing a second test message exchange with the detected single use storage device.

Example 26 is the system of Example 25, wherein the operations include locking in the second voltage of the plurality of DC voltages at the selector if the second test message exchange is successful.

Example 27 is the system of Example 25, wherein the operations include selecting a third voltage of the plurality of DC voltages, the third voltage being a higher voltage than the second voltage of the plurality of DC voltages, if the second test message exchange is unsuccessful, and translating the single-use-device data storage voltage to the third voltage of the plurality of DC voltages.

Example 28 is the system of Example 27, wherein the operations include performing a third test message exchange with the detected single use storage device.

Example 29 is the system of Example 28, wherein the operations include locking in the third voltage of the plurality of DC voltages at the selector if the second test message exchange is successful.

Example 30 is the system of Example 28, wherein the operations include selecting a fourth voltage of the plurality of DC voltages, the fourth voltage being a higher voltage than the third voltage of the plurality of DC voltages, if the third test message exchange is unsuccessful, and translating the single-use-device data storage voltage to the fourth voltage of the plurality of DC voltages.

Example 31 is a method for adapting long-lived capital equipment to changing single-use-device data storage technology. The method includes detecting the presence of a single-use-device data storage. The method includes selecting a first voltage of a plurality of DC voltages from a power supply. The method includes translating a single-use-device data storage voltage to the first voltage of the plurality of DC voltages, and performing a first test message exchange with the detected single use storage device.

Example 32 is the method of Example 31, further including locking in the first voltage of the plurality of DC voltages at a selector if the first test message exchange is successful.

Example 33 is the method of Example 31, further including selecting a second voltage of the plurality of DC voltages, the second voltage being higher voltage than the first voltage of the plurality of DC voltages, if the first test message exchange is unsuccessful, translating the single-use-device data storage voltage to the second voltage of the plurality of DC voltages, and performing a second test message exchange with the detected single use storage device.

Example 34 is the method of Example 33, further including locking in the second voltage of the plurality of DC voltages at a selector if the second test message exchange is successful.

Example 35 is the method of Example 33, further including selecting a third voltage of the plurality of DC voltages, the third voltage being a higher voltage than the second voltage of the plurality of DC voltages, if the second test message exchange is unsuccessful, and translating the single-use-device data storage voltage to the third voltage of the plurality of DC voltages.

While multiple embodiments are disclosed, still other embodiments of the present disclosure will become apparent to those skilled in the art from the following detailed description, which shows and describes illustrative embodiments of the disclosure. Accordingly, the drawings and detailed description are to be regarded as illustrative in nature and not restrictive.

### BRIEF DESCRIPTION OF THE DRAWINGS

FIG. 1 is a schematic representation of a first embodiment of a system for adapting long-lived capital equipment to changing single-use-device data storage technology, in accordance with the disclosure.

FIG. 2 is a schematic representation of a second embodiment of a system for adapting long-lived capital equipment to changing single-use-device data storage technology, in accordance with the disclosure.

FIG. 3 is a schematic representation of a third embodiment of a system for adapting long-lived capital equipment to changing single-use-device data storage technology, in accordance with the disclosure.

FIG. 4 is a schematic representation of a fourth embodiment of a system for adapting long-lived capital equipment to changing single-use-device data storage technology, in accordance with the disclosure.

FIG. 5 is a schematic representation of a fifth embodiment of a system for adapting long-lived capital equipment to changing single-use-device data storage technology, in accordance with the disclosure.

FIG. 6 illustrates a control system for adapting long-lived capital equipment to changing single-use-device data storage technology, in accordance with the disclosure.

FIG. 7 illustrates a method for adapting long-lived capital equipment to changing single-use-device data storage technology, in accordance with the disclosure.

While the disclosure is amenable to various modifications and alternative forms, specific embodiments have been shown by way of example in the drawings and are described in detail below. The intention, however, is not to limit the disclosure to the particular embodiments described. On the contrary, the disclosure is intended to cover all modifications, equivalents, and alternatives falling within the scope of the disclosure as defined by the appended claims.

### DETAILED DESCRIPTION

For purposes of promoting an understanding of the principles of the present disclosure, reference is now made to the examples illustrated in the drawings, which are described below. The illustrated examples disclosed herein are not intended to be exhaustive or to limit the disclosure to the precise form disclosed in the following detailed description. Rather, these exemplary embodiments were chosen and described so that others skilled in the art may use their teachings. It is not beyond the scope of this disclosure to have a number (e.g., all) the features in a given example used across all examples. Thus, no one figure should be interpreted as having any dependency or requirement related to any single component or combination of components illustrated therein. Additionally, various components depicted in a given figure may be, in examples, integrated with various ones of the other components depicted therein (and/or components not illustrated), all of which are considered to be within the ambit of the present disclosure.

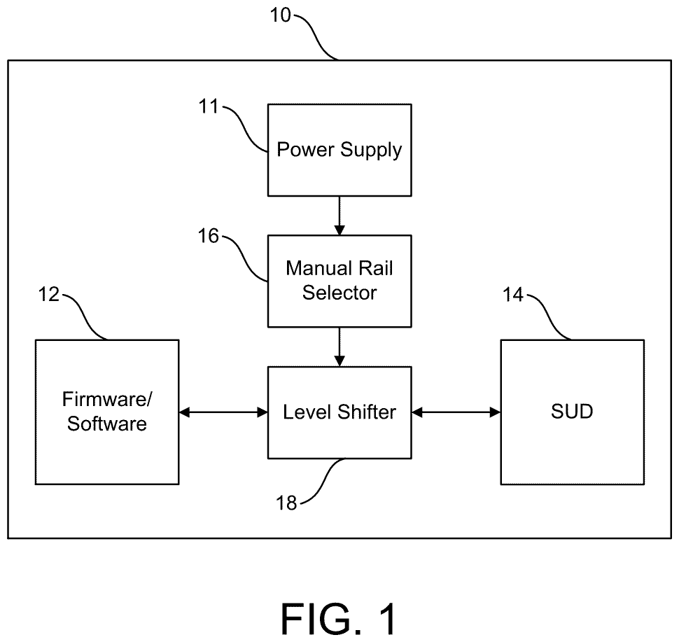

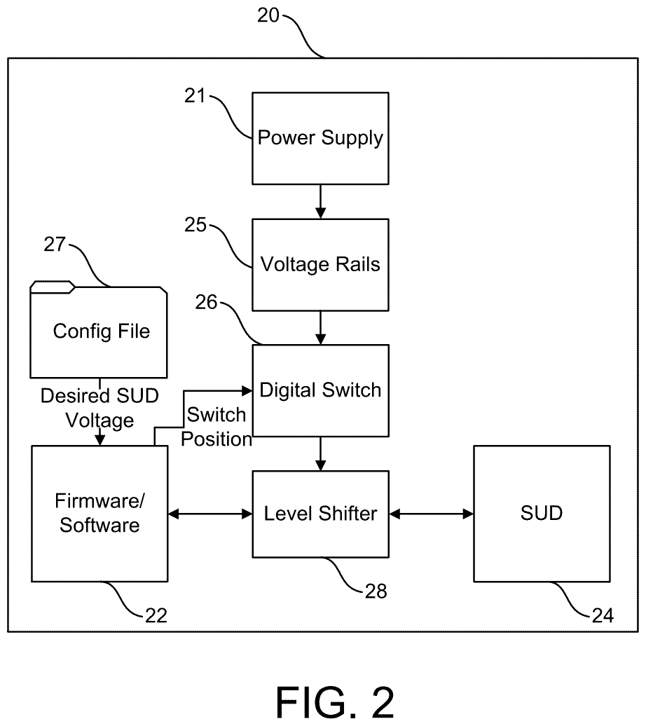

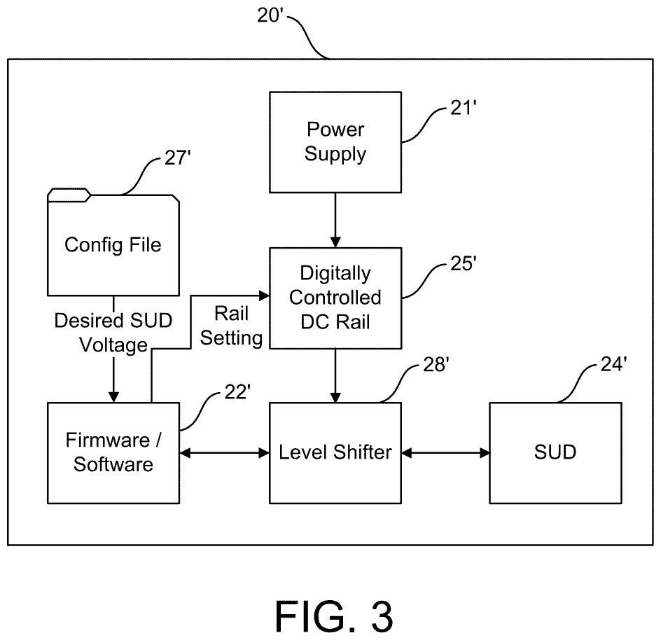

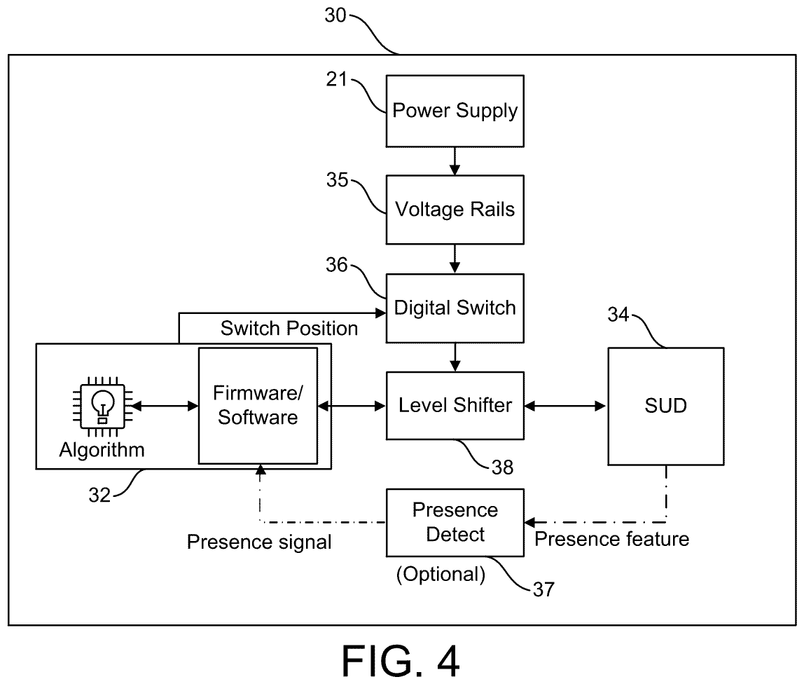

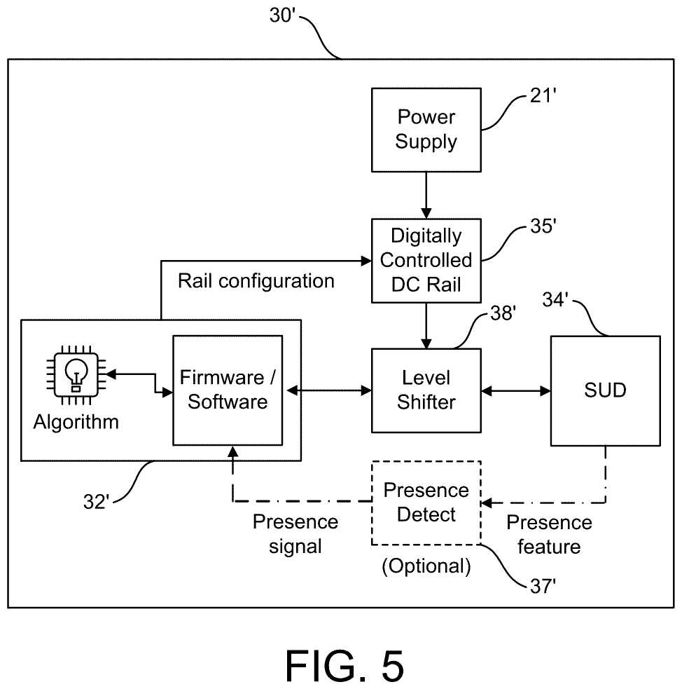

FIGS. 1-5 illustrate several embodiments of systems for adapting long-lived capital equipment to changing single-use-device data storage technology. Each embodiment relies on a voltage-translator circuit. On one side of a translator, a fixed voltage level is provided at a firmware chip, for example a field-programmable gate array (FPGA). The other side of the translator is connected to SUD data storage. A switch is connected to a plurality of voltage rail inputs. The switch is configured to select one of the plurality of voltage rail inputs and to be fed to the translator. In the embodiment of FIG. 1, the switch is a manual switch. In the embodiments of FIGS. 2 and 4, the switch is a digitally controlled switch. In the embodiments of FIGS. 3 and 5, a digitally controlled voltage rail functions as a switch.

FIG. 1 is a schematic representation of a first embodiment of a system for adapting long-lived capital equipment 10 to changing single-use-device data storage technology, in accordance with the disclosure. FIG. 1 illustrates a simple, manual variant that allows service technicians to modify the voltage level used by the capital equipment 10 to communicate with a single-use-device data storage 14. This variant has a manual voltage rail selector 16 configured to select one of a plurality of voltages created by a power supply 11 that converts AC power into a plurality of DC voltages. A selected voltage feeds into a level shifter 18 to translate the single-use-device data storage 14 voltage into a voltage level that the firmware/software 12 is able to understand and communicate with.

In the embodiment illustrated in FIG. 1, the voltage level selected with the rail elector 16 is determined by manufacturing personnel during initial manufacturing of the capital equipment 10, or at a later time by service personnel, for example during a service call that requires replacement or upgrade of the single-use-device data storage 14. The voltage level can be changed manually by a service action. This allows for service personnel to modify capital equipment 10 to make it compatible with a new voltage level required by replacement single-use-device data storage 14 sourced by a supply chain team. No hardware upgrade is required on the capital equipment 10 to make it compatible with the new voltage level.

FIG. 2 is a schematic representation of a second embodiment of a system for adapting long-lived capital equipment 20 to changing single-use-device data storage technology, in accordance with the disclosure. Unlike the embodiment disclosed in FIG. 1, the Embodiment of FIG. 2 does not require manual switching by manufacturing or service personnel.

The capital equipment 20 of FIG. 2 includes a power supply 21 that converts AC power into a plurality of DC voltages. The plurality of DC voltages are provided on a plurality of voltage rails 25. A digital switch 26 is controlled by firmware/software 22 in the capital equipment 20. The firmware/software 22 communicates with a configuration file 27 that includes information associated with proper voltage levels related to various single-use-device data storage 24. The software/firmware 22 updates a digital switch 26 position to select a proper voltage rail 25 in order to properly configure the current voltage level of the SUD 24 based on the configuration file 27. This digital switch 26 feeds into a level shifter 28 to translate the SUD 24 voltage into a voltage level that the firmware/software 22 is able to understand and communicate with. In some aspects, a software/firmware update can initiate a selection of a proper voltage level.

FIG. 3 is a schematic representation of a third embodiment of a system for adapting long-lived capital equipment 20′ to changing single-use-device data storage technology, in accordance with the disclosure. The system of FIG. 3 is similar to the system of FIG. 2, with the exception of a digitally controlled voltage rail 25′.

The capital equipment 20′ of FIG. 3 includes a power supply 21′ that converts AC power into a plurality of DC voltages. The plurality of DC voltages are provided to a digitally controlled voltage rail 25′. The digitally controlled voltage rail 25′ is controlled by firmware/software 22′ in the capital equipment 20′. The firmware/software 2′2 communicates with a configuration file 27′ that includes information associated with proper voltage levels related to various single-use-device data storage 24′. The software/firmware 22′ updates the digitally controlled voltage rail 25′ to properly configure the current voltage level of the SUD 24′ based on the configuration file 27′. The digitally controlled voltage rail 25′ feeds into a level shifter 28′ to translate the SUD 24′ voltage into a voltage level that the firmware/software 22′ is able to understand and communicate with. In some aspects, a software/firmware update can initiate a selection of a proper voltage level.

FIG. 4 is a schematic representation of a fourth embodiment of a system for adapting long-lived capital equipment 30 to changing single-use-device data storage technology, in accordance with the disclosure. The embodiment of FIG. 4 is similar to the embodiment of FIG. 2. However, rather than having a configuration file, the software/firmware 32 includes an algorithm to select a proper voltage level in order to allow the software/firmware 32 of the capital equipment 30 to communicate with a single-use data storage 34. This variant has a digital switch voltage rail selector 36 feeding into a level shifter 38 to translate the SUD 34 voltage into a voltage level that the firmware/software 32 is able to understand. Additionally, the SUD 34 also has a binary presence feature such that a presence detector 37 can determine when the SUD 34 is connected.

FIG. 5 is a schematic representation of a fifth embodiment of a system for adapting long-lived capital equipment 30 to changing single-use-device data storage technology, in accordance with the disclosure. The system of FIG. 5 is similar to the system of FIG. 4, with the exception of a digitally controlled voltage rail 35′. The digitally controlled voltage rail 35′ feeds into a level shifter 38′ to translate the SUD 34′ voltage into a voltage level that the firmware/software 32′ is able to understand. Additionally, the SUD 34′ also has a binary presence feature such that a presence detector 37′ can determine when the SUD 34′ is connected.

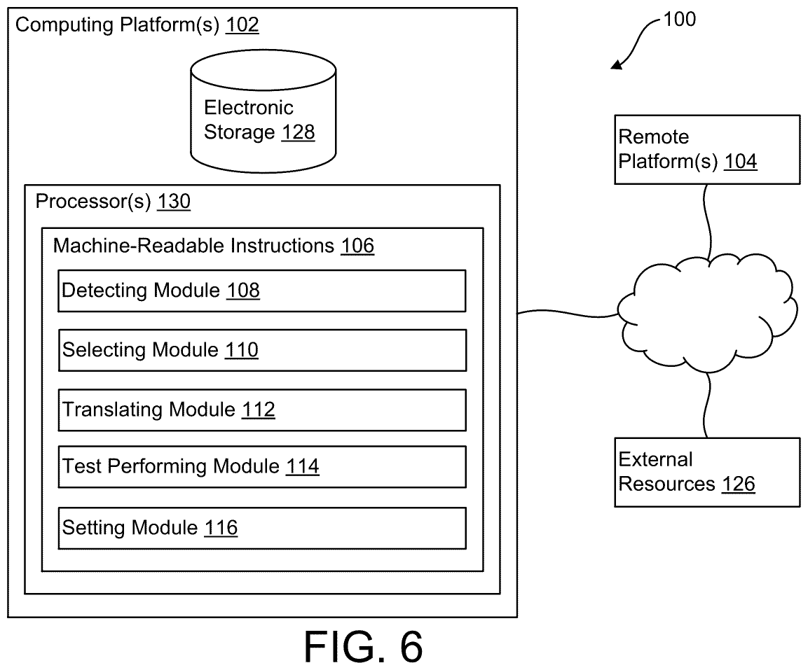

FIG. 6 illustrates a control system 100 configured for adapting long-lived capital equipment to changing single-use-device data storage technology, in accordance with one or more implementations. In some implementations, system 100 may include one or more computing platforms 102. Computing platform(s) 102 may be configured to communicate with one or more remote platforms 104 according to a client/server architecture, a peer-to-peer architecture, and/or other architectures. Remote platform(s) 104 may be configured to communicate with other remote platforms via computing platform(s) 102 and/or according to a client/server architecture, a peer-to-peer architecture, and/or other architectures. Users may access system 100 via remote platform(s) 104.

Computing platform(s) 102 may be configured by machine-readable instructions 106. Machine-readable instructions 106 may include one or more instruction modules. The instruction modules may include computer program modules. The instruction modules may include one or more of detecting module 108, selecting module 110, translating module 112, test performing module 114, setting module 116, and/or other instruction modules.

Detecting module 108 is configured to detect the presence of a single-use-device data storage. Detecting module 108 may interact with a presence detector to determine when a SUD data storage is connected. Alternatively, the detecting module 108 selects a neutral voltage level that can elicit “presence” pulses by all voltage-level

devices in a system. The detecting module 108 performs “polling” on a communication bus by generating these pulses until a presence pulse of a SUD data storage is detected.

Selecting module 110 is configured to select one of a plurality of DC voltages from a power supply. The selecting module 110 can select of a plurality of DC voltages to be fed into a level shifter to translate a single-use-device data storage voltage into a different voltage level. In some embodiments, the selecting module 110 may use information from a configuration file to select one of the plurality of DC voltage rails. In other embodiments, the selecting module 110 may use an algorithm to select one of the plurality of DC voltage rails.

Translating module 112 is configured to translate a single-use-device data storage voltage to a voltage selected by the selecting module 110. The translating module 112 can include a level shifter to translate the single-use-device data storage voltage to the voltage selected by the selecting module 110.

Test performing module 114 is configured to perform one or more test message exchanges with a single-use-device data storage. The one or more test message exchanges can include one or more query, call, input, or other interaction with a single-use-device data storage. The one or more test message exchanges is performed to identify when a single-use-device data storage has a voltage that allows interaction and communication with firmware/software of a capital equipment system.

Setting module 116 is configured to lock in a voltage of the plurality of DC voltages at a selector if a test message exchange performed by the test performing module 114 is successful.

In some implementations, computing platform(s) 102, remote platform(s) 104, and/or external resources 126 may be operatively linked via one or more electronic communication links. For example, such electronic communication links may be established, at least in part, via a network such as the Internet and/or other networks. It will be appreciated that this is not intended to be limiting, and that the scope of this disclosure includes implementations in which computing platform(s) 102, remote platform(s) 104, and/or external resources 126 may be operatively linked via some other communication media.

A given remote platform 104 may include one or more processors configured to execute computer program modules. The computer program modules may be configured to enable an expert or user associated with the given remote platform 104 to interface with system 100 and/or external resources 126, and/or provide other functionality attributed herein to remote platform(s) 104. By way of non-limiting example, a given remote platform 104 and/or a given computing platform 102 may include one or more of a server, a desktop computer, a laptop computer, a handheld computer, a tablet computing platform, a NetBook, a Smartphone, a gaming console, and/or other computing platforms.

External resources 126 may include sources of information outside of system 100, external entities participating with system 100, and/or other resources. In some implementations, some or all of the functionality attributed herein to external resources 126 may be provided by resources included in system 100.

Computing platform(s) 102 may include electronic storage 128, one or more processors 130, and/or other components. Computing platform(s) 102 may include communication lines, or ports to enable the exchange of information with a network and/or other computing platforms. Illustration of computing platform(s) 102 in FIG. 4 is not intended to be limiting. Computing platform(s) 102 may include a plurality of hardware, software, and/or firmware components operating together to provide the functionality attributed herein to computing platform(s) 102. For example, computing platform(s) 102 may be implemented by a cloud of computing platforms operating together as computing platform(s) 102.

Electronic storage 128 may comprise non-transitory storage media that electronically stores information. The electronic storage media of electronic storage 128 may include one or both of system storage that is provided integrally (i.e., substantially non-removable) with computing platform(s) 102 and/or removable storage that is removably connectable to computing platform(s) 102 via, for example, a port (e.g., a USB port, a firewire port, etc.) or a drive (e.g., a disk drive, etc.). Electronic storage 128 may include one or more of optically readable storage media (e.g., optical disks, etc.), magnetically readable storage media (e.g., magnetic tape, magnetic hard drive, floppy drive, etc.), electrical charge-based storage media (e.g., EEPROM, RAM, etc.), solid-state storage media (e.g., flash drive, etc.), and/or other electronically readable storage media. Electronic storage 128 may include one or more virtual storage resources (e.g., cloud storage, a virtual private network, and/or other virtual storage resources). Electronic storage 128 may store software algorithms, information determined by processor(s) 130, information received from computing platform(s) 102, information received from remote platform(s) 104, and/or other information that enables computing platform(s) 102 to function as described herein.

Processor(s) 130 may be configured to provide information processing capabilities in computing platform(s) 102. As such, processor(s) 130 may include one or more of a digital processor, an analog processor, a digital circuit designed to process information, an analog circuit designed to process information, a state machine, and/or other mechanisms for electronically processing information. Although processor(s) 130 is shown in FIG. 6 as a single entity, this is for illustrative purposes only. In some implementations, processor(s) 130 may include a plurality of processing units. These processing units may be physically located within the same device, or processor(s) 130 may represent processing functionality of a plurality of devices operating in coordination. Processor(s) 130 may be configured to execute modules 108, 110, 112, 114, and/or 116, and/or other modules. Processor(s) 130 may be configured to execute modules 108, 110, 112, 114, and/or 116, and/or other modules by software; hardware; firmware; some combination of software, hardware, and/or firmware; and/or other mechanisms for configuring processing capabilities on processor(s) 130. As used herein, the term “module” may refer to any component or set of components that perform the functionality attributed to the module. This may include one or more physical processors during execution of processor readable instructions, the processor readable instructions, circuitry, hardware, storage media, or any other components.

It should be appreciated that although modules 108, 110, 112, 114, and/or 116 are illustrated in FIG. 6 as being implemented within a single processing unit, in implementations in which processor(s) 130 includes multiple processing units, one or more of modules 108, 110, 112, 114, and/or 116 may be implemented remotely from the other modules. The description of the functionality provided by the different modules 108, 110, 112, 114, and/or 116 described below is for illustrative purposes, and is not intended to be limiting, as any of modules 108, 110, 112, 114, and/or 116 may provide more or less functionality than is described. For example, one or more of modules 108, 110, 112, 114, and/or 116 may be eliminated, and some or all of its functionality may be provided by other ones of modules 108, 110, 112, 114, and/or 116. As another example, processor(s) 130 may be configured to execute one or more additional modules that may perform some or all of the functionality attributed below to one of modules 108, 110, 112, 114, and/or 116.

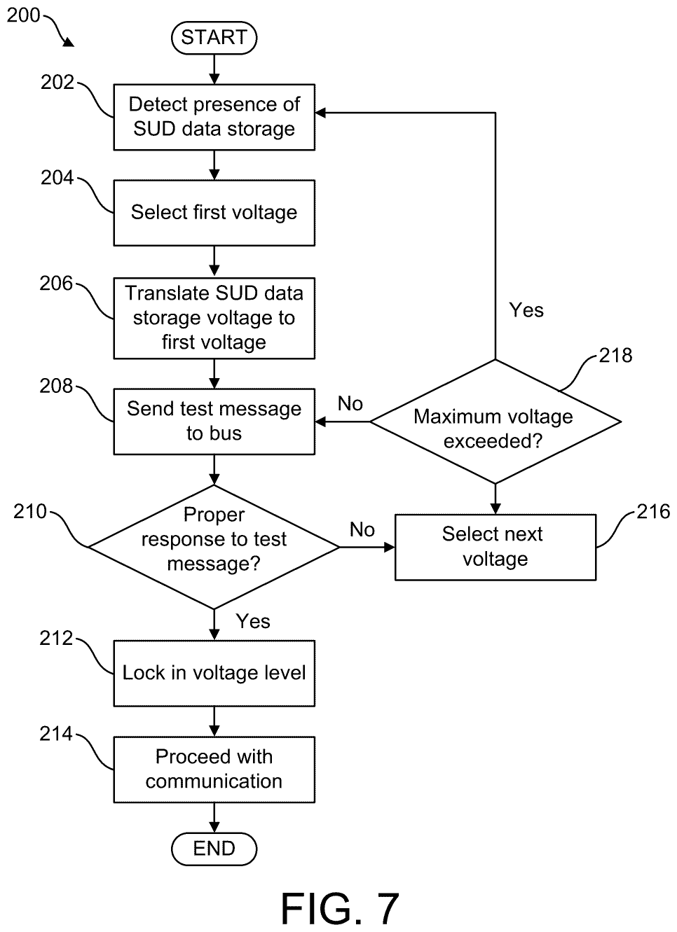

FIG. 7 illustrates a method 200 for adapting long-lived capital equipment to changing single-use-device data storage technology, in accordance with one or more implementations. The operations of method 200 presented below are intended to be illustrative. In some implementations, method 200 may be accomplished with one or more additional operations not described, and/or without one or more of the operations discussed. Additionally, the order in which the operations of method 200 are illustrated in FIG. 4 and described below is not intended to be limiting.

In some implementations, method 200 may be implemented in one or more processing devices (e.g., a digital processor, an analog processor, a digital circuit designed to process information, an analog circuit designed to process information, a state machine, and/or other mechanisms for electronically processing information) in combination with hardware components or circuitry. The one or more processing devices may include one or more devices executing some or all of the operations of method 200 in response to instructions stored electronically on an electronic storage medium. The one or more processing devices may include one or more devices configured through hardware, firmware, and/or software to be specifically designed for execution of one or more of the operations of method 200.

An operation 202 may include detecting the presence of a single-use-device data storage. In some embodiments, a presence detector may determine when a SUD data storage is connected to the capital equipment system. Alternatively, a neutral “safe” voltage level that can elicit “presence” pulses by all voltage-level devices in a system can be “polled” on a communication bus until a presence pulse of a SUD data storage is detected. The “safe” voltage level is low enough to ensure no damage to any connected SUD data storage. Operation 202 may be performed by one or more hardware processors configured by machine-readable instructions including a module that is the same as or similar to detecting module 108 in combination with hardware and/or circuitry, in accordance with one or more implementations. Once the presence of a SUD data storage is confirmed, the method moves to operation 204.

An operation 204 includes selecting a first voltage of a plurality of DC voltages from a power supply and setting the voltage rail to the first voltage. Operation 204 may be performed by one or more hardware processors configured by machine-readable instructions including a module that is the same as or similar to selecting module 110 in combination with hardware and/or circuitry, in accordance with one or more implementations. In one aspect, the first voltage can be any of the plurality of DC voltages from the power supply. In another aspect, the first voltage can be the highest of the plurality of DC voltages from the power supply. In another aspect, the first voltage level can be the lowest of the plurality of DC voltages from the power supply.

An operation 206 may include translating a single-use-device data storage voltage to the first voltage of the plurality of DC voltages. Operation 206 may be performed by one or more hardware processors configured by machine-readable instructions including a module that is the same as or similar to translating module 112 in combination with hardware and/or circuitry, in accordance with one or more implementations.

An operation 208 may include performing a test message exchange with a detected single-use-device data storage. This can include sending a generic request to the detected single-use-device data storage. For example, a known register read request may be sent to the detected single-use-device data storage. The first test message exchanges can include one or more query, call, input, or other interaction with a single-use-device data storage. The test message exchange is performed to identify when a single-use-device data storage has a voltage that allows interaction and communication with firmware/software of a capital equipment system Operation 208 may be performed by one or more hardware processors configured by machine-readable instructions including a module that is the same as or similar to test performing module 114, in accordance with one or more implementations.

An operation 210 includes determining if a proper response or valid message is received in response to the test message. If a proper response is received, the method 200 moves to operation 212 in which the first voltage is locked in at the selector. We now “lock” that voltage level until either the generator is shut down, or for a certain amount of time after the last SUD data storage was disconnected. Operation 210 may be performed by one or more hardware processors configured by machine-readable instructions including a module that is the same as or similar to setting module 116, in accordance with one or more implementations. At this point, communication between firmware/software of the capital equipment system and the SUD can be carried out at operation 214.

If a proper response is not received, the method 200 moves to operation 216 in which includes selecting a next voltage of a plurality of DC voltages from a power supply and setting the voltage rail to the next voltage. In some aspects, selecting a next voltage includes increasing the voltage. In some aspects, selecting a next voltage includes reducing the voltage. In some aspects, selecting a next voltage includes selecting the lowest possible voltage of the plurality of DC voltages. In some aspects, selecting a next voltage includes selecting the highest possible voltage of the plurality of DC voltages Operation 216 may be performed by one or more hardware processors configured by machine-readable instructions including a module that is the same as or similar to selecting module 110 in combination with hardware and/or circuitry, in accordance with one or more implementations.

At operation 218 it is determined whether or not a maximum voltage is exceeded for the system. If a maximum voltage is not exceeded, then the method 200 includes translating the single-use-device data storage voltage to the next voltage of the plurality of DC voltages. This can be performed by one or more hardware processors configured by machine-readable instructions including a module that is the same as or similar to translating module 112 in combination with hardware and/or circuitry, in accordance with one or more implementations. If a maximum voltage is exceeded, the method 200 can begin again by setting a “safe” neutral voltage and querying for the presence of SUD data storage.

The method returns to operation 208, where a test message exchange is performed with the single-use-device data storage and the next voltage level. This can include sending a generic request to the detected single-use-device data storage. For example, a known register read request may be sent to the detected single-use-device data storage. The next test message exchanges can include one or more query, call, input, or other interaction with a single-use-device data storage. Operation 208 may be performed by one or more hardware processors configured by machine-readable instructions including a module that is the same as or similar to test performing module 114, in accordance with one or more implementations.

The method 200 thus continues until a valid message is received at operation 210 and the current voltage level is locked and set as the operating voltage for the capital equipment system.

It is well understood that methods that include one or more steps, the order listed is not a limitation of the claim unless there are explicit or implicit statements to the contrary in the specification or claim itself. It is also well settled that the illustrated methods are just some examples of many examples disclosed, and certain steps may be added or omitted without departing from the scope of this disclosure. Such steps may include incorporating devices, systems, or methods or components thereof as well as what is well understood, routine, and conventional in the art.

The connecting lines shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements. The scope is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B or C may be present in a single embodiment; for example, A and B, A and C, B and C, or A and B and C. The terms “couples,” “coupled,” “connected,” “attached,” and the like along with variations thereof are used to include both arrangements wherein two or more components are in direct physical contact and arrangements wherein the two or more components are not in direct contact with each other (e.g., the components are “coupled” via at least a third component), but still cooperate or interact with each other.

In the detailed description herein, references to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art with the benefit of the present disclosure to affect such feature, structure, or characteristic in connection with other embodiments whether or not explicitly described. After reading the description, it will be apparent to one skilled in the relevant art(s) how to implement the disclosure in alternative embodiments.

Various modifications and additions can be made to the exemplary embodiments discussed without departing from the scope of the present disclosure. For example, while the embodiments described above refer to particular features, the scope of this disclosure also includes embodiments having different combinations of features and embodiments that do not include all of the described features. Accordingly, the scope of the present disclosure is intended to embrace all such alternatives, modifications, and variations as fall within the scope of the claims, together with all equivalents thereof.

We claim:

1. A system for adapting long-lived capital equipment to changing single-use-device data storage technology, the system comprising:
one or more memory devices storing instructions;
one or more processors configured to execute the instructions to perform operations;
a power supply configured to convert AC power into a plurality of DC voltages;
a selector configured to select one of the plurality of DC voltages; and
a level shifter configured to receive the selected one of the plurality of DC voltages and to translate a single-use-device data storage voltage to the selected one of the plurality of DC voltages.

2. The system of claim 1, wherein the selector is a manual voltage rail selector.

3. The system of claim 1, wherein the selector is a digital switch voltage rail selector or a digitally controlled voltage rail that is controlled by a configuration file.

4. The system of claim 3, further comprising a binary presence feature configured to identity that a single-use-device data storage is connected to the system.

5. The system of claim 4, wherein the configuration file controls the digital switch voltage rail selector based on information from the binary presence feature.

6. The system of claim 1, wherein the operations include:
detecting the presence of a single-use-device data storage;
selecting a first voltage of the plurality of DC voltages, the first voltage being a lowest of the plurality of DC voltages; and
translating a single-use-device data storage voltage to the first voltage of the plurality of DC voltages.

7. The system of claim 6, wherein the operations include:
performing a first test message exchange with the detected single use storage device.

8. The system of claim 7, wherein the operations include:
locking in the first voltage of the plurality of DC voltages at the selector if the first test message exchange is successful.

9. The system of claim 7, wherein the operations include:
selecting a second voltage of the plurality of DC voltages, the second voltage being a higher voltage than the first voltage of the plurality of DC voltages, if the first test message exchange is unsuccessful; and
translating the single-use-device data storage voltage to the second voltage of the plurality of DC voltages.

10. The system of claim 9, wherein the operations include:
performing a second test message exchange with the detected single use storage device.

11. The system of claim 10, wherein the operations include:
locking in the second voltage of the plurality of DC voltages at the selector if the second test message exchange is successful.

12. The system of claim 10, wherein the operations include:
selecting a third voltage of the plurality of DC voltages, the third voltage being a higher voltage than the second voltage of the plurality of DC voltages, if the second test message exchange is unsuccessful; and
translating the single-use-device data storage voltage to the third voltage of the plurality of DC voltages.

13. The system of claim 12, wherein the operations include:
performing a third test message exchange with the detected single use storage device.

14. The system of claim 13, wherein the operations include:
locking in the third voltage of the plurality of DC voltages at the selector if the third test message exchange is successful.

15. The system of claim 13, wherein the operations include:
selecting a fourth voltage of the plurality of DC voltages, the fourth voltage being a higher voltage than the third voltage of the plurality of DC voltages, if the third test message exchange is unsuccessful; and
translating the single-use-device data storage voltage to the fourth voltage of the plurality of DC voltages.

16. A method for adapting long-lived capital equipment to changing single-use-device data storage technology, the method comprising:
detecting the presence of a single-use-device data storage;
selecting a first voltage of a plurality of DC voltages from a power supply;
translating a single-use-device data storage voltage to the first voltage of the plurality of DC voltages; and
performing a first test message exchange with the detected single use storage device.

17. The method of claim 16, further comprising:
locking in the first voltage of the plurality of DC voltages at a selector if the first test message exchange is successful.

18. The method of claim 16, further comprising:
selecting a second voltage of the plurality of DC voltages, the second voltage being a higher voltage than the first voltage of a plurality of DC voltages, if the first test message exchange is unsuccessful;
translating the single-use-device data storage voltage to the second voltage of the plurality of DC voltages; and
performing a second test message exchange with the detected single use storage device.

19. The method of claim 18, further comprising:
locking in the second voltage of the plurality of DC voltages at a selector if the second test message exchange is successful.

20. The method of claim 18, further comprising:
selecting a third voltage of the plurality of DC voltages, the third voltage being a higher voltage than the second voltage of the plurality of DC voltages, if the second test message exchange is unsuccessful; and
translating the single-use-device data storage voltage to the third voltage of the plurality of DC voltages.
